(19) United States
(12) Patent Application Publication
(10) Pub. No.: US 2020/0216961 A1
(43) Pub. Date: Jul. 9, 2020

(54) SUBSTRATE PROCESSING APPARATUS, A NON-TRANSITORY COMPUTER-READABLE RECORDING MEDIUM

(71) Applicant: KOKUSAI ELECTRIC CORPORATION, Tokyo (JP)

(72) Inventors: Makoto NOMURA, Toyama (JP); Yasuhiro MIZUGUCHI, Toyama (JP); Kazuhito SAITO, Toyama (JP); Takashi YOKAWA, Toyama (JP); Makoto SHIRAKAWA, Toyama (JP); Masako SUEYOSHI, Toyama (JP)

(73) Assignee: KOKUSAI ELECTRIC CORPORATION, Tokyo (JP)

(21) Appl. No.: 16/824,286

(22) Filed: Mar. 19, 2020

Related U.S. Application Data
(63) Continuation of application No. PCT/JP2018/009440, filed on Mar. 12, 2018.

(30) Foreign Application Priority Data
Sep. 20, 2017 (JP) 2017-179784

(51) Int. Cl. C23C 16/52; H01J 37/32; H01L 21/67; H01L 21/677; C23C 16/505

(52) U.S. Cl. CPC C23C 16/52; H01J 37/32458; H01J 37/3211; H01J 37/3244; H01L 21/67248; H01L 21/67742; H01J 2237/3321; H01L 21/67201; H01J 37/32724; H01L 21/67167; C23C 16/505; H01J 2237/24564; H01J 2237/24585; H01J 37/32899

(57) ABSTRACT

A processing container including a plasma generation space in which a processing gas is plasma-excited and a substrate processing space communicating with the plasma generation space; a plasma generator including a coil arranged to surround the plasma generation space and provided to be wound around an outer periphery of the processing container, and a high-frequency power source that supplies high-frequency power to the coil; a gas supply section that supplies the processing gas to the plasma generation space; a temperature sensor provided outside the processing container and configured to detect a temperature of the processing container; and a controller configured to perform control to cause the temperature of the processing container detected by the temperature sensor to fall within a range of a target temperature defined by a preset upper limit value and a preset lower limit value, prior to execution of a process recipe for processing a substrate.

### CROSS-REFERENCE TO RELATED APPLICATION

This application is a Bypass Continuation Application of PCT International Application No. PCT/JP2018/009440, filed on Mar. 12, 2018, which claims priority to JP 2017-179784, filed on Sep. 20, 2017, the entire contents of which are incorporated herein by reference.

### TECHNICAL FIELD

This present disclosure relates to a substrate processing apparatus, a non-transitory computer-readable recording medium.

### BACKGROUND

In recent years, semiconductor devices such as flash memories have been highly integrated. Accordingly, the pattern size is remarkably miniaturized. When these patterns are formed, a step of performing predetermined processing such as an oxidizing or nitriding on a substrate may be performed as one step in a manufacturing step.

For example, as known in the related art, a modification processing on a pattern surface formed on a substrate by using a plasma-excited processing gas is performed.

### SUMMARY

Currently, processing of several dummy substrates is executed as pre-processing for substrate processing, whereby the temperature of a quartz dome is increased, and then a product lot (product substrate group) is processed, so that there is a concern that productivity is decreased.

This present disclosure provides a recipe execution control for executing pre-processing without using a dummy substrate before processing a product lot.

According to one embodiment of this present disclosure, a configuration is provided including: at least one of a process container including a plasma generation space in which a processing gas is plasma-excited and a substrate processing space communicating with the plasma generation space; a plasma generator including a coil arranged to surround the plasma generation space and provided to be wound around an outer periphery of the process container, and a high-frequency power source that supplies high-frequency power to the coil; a gas supply section that supplies the processing gas to the plasma generation space; at least one of a temperature sensor provided outside the at least one of the process container and configured to detect a temperature of the at least one of the process container; and a controller configured to perform a control to cause the temperature of the at least one of the process container detected by the at least one of the temperature sensor to fall within a range of a target temperature defined by a preset upper limit value and a preset lower limit value, prior to execution of a process recipe for processing substrates.

### BRIEF DESCRIPTION OF DRAWINGS

FIG. 1 is a configuration diagram (top view) of a substrate processing apparatus according to an embodiment of this present disclosure.

FIG. 2 is a schematic cross-sectional view of the substrate processing apparatus according to the embodiment of this present disclosure.

FIG. 3 is a diagram illustrating a configuration of a controller (control means) of the substrate processing apparatus according to the embodiment of the present disclosure.

FIG. 4 is a flow diagram illustrating a substrate processing step according to the embodiment of the present disclosure.

FIG. 5 is an illustrated example of a sequence recipe editing screen according to the embodiment of the present disclosure.

FIG. 6A illustrates an example of a flow of a pre-processing recipe according to the embodiment of the present disclosure.

FIG. 6B illustrates an example of the flow of the pre-processing recipe according to the embodiment of the present disclosure.

FIG. 7 illustrates an example of the flow of the pre-processing recipe according to the embodiment of the present disclosure.

### DETAILED DESCRIPTION

### First Embodiment of the Present Disclosure

### (1) Configuration of Substrate Processing Apparatus

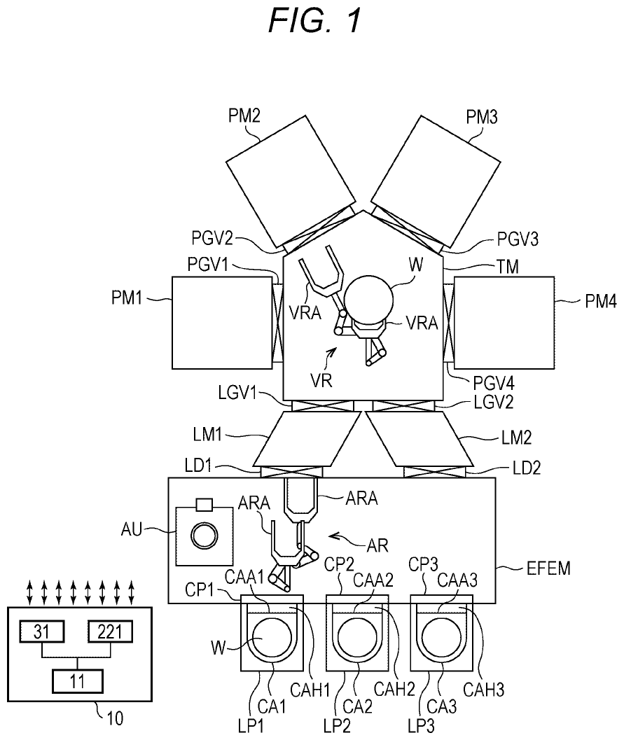

A substrate processing apparatus according to a first embodiment of the present disclosure will be described below with reference to FIG. 1.

The substrate processing apparatus illustrated in FIG. 1 includes a vacuum side configuration for handling a substrate (for example, a wafer W made of silicon or the like) in a reduced pressure state, and an atmospheric pressure side configuration for handling the wafer W in an atmospheric pressure state. The vacuum side configuration mainly includes a vacuum transfer chamber TM, load lock chambers LM1 and LM2, and processing modules (processing mechanisms) PP1 to PM4 for processing the wafer W. The atmospheric pressure side configuration mainly includes an atmospheric pressure transfer chamber EFEM, and load ports LP1 to LP3. Carriers CA1 to CA3 storing wafers W are transferred from the outside of the substrate processing apparatus and mounted on the load ports LP1 to LP3, and are also transferred to the outside of the substrate processing apparatus. According to this configuration, for example, an unprocessed wafer W is taken out from the carrier CA1 on the load port LP1, and is loaded into the processing module PP1 via the load lock chamber LM1 and is processed, and then the processed wafer W is returned to the carrier CA1 on the load port LP1 in the reverse procedure.

(Vacuum Side Configuration)

The vacuum transfer chamber TM has a vacuum-tight structure capable of withstanding a negative pressure (reduced pressure) less than atmospheric pressure such as a vacuum state. In addition, in the present embodiment, a housing of the vacuum transfer chamber TM is formed in a box shape having a pentagonal shape in plan view and closed at both upper and lower ends. The load lock chambers LM1 and LM2, and the processing modules PM1 to PM4 are arranged to surround the outer periphery of the vacuum transfer chamber TM. The processing modules PM1 to PM4 will be generally or representatively referred to as processing module PM. The load lock chambers LM1 and LM2 will be generally or representatively referred to as a load lock chamber LM. The same rules apply to other components (a vacuum robot VR, an arm VRA, and the like, which will be described later).

In the vacuum transfer chamber TM, for example, one vacuum robot VR is provided as a transfer means for transferring the wafer W in a reduced pressure state. The vacuum robot VR is configured to transfer the wafer W between the load lock chamber LM and the processing module PM by mounting the wafer W on two sets of substrate support arms (hereinafter referred to as arms) VRA that are substrate mounting sections. The vacuum robot VR is configured to be able to move up and down while maintaining the airtightness of the vacuum transfer chamber TM. Furthermore, the two sets of arms VRA are installed to be vertically separated from each other so as to be each expanded and contracted in a horizontal direction, and are configured to move rotatably in the relevant horizontal plane.

Each of the processing modules PM includes a substrate mounting section on which the wafer W is mounted, and is configured as a single wafer process chamber for processing, for example, the wafers W one by one in a reduced pressure state. That is, each of the processing module PM serves as a process chamber for giving added value to the wafer W, such as etching or ashing using plasma or the like, or film formation by chemical reaction.

Each of the processing modules PM is connected to the vacuum transfer chamber TM by gate valves PGV as opening/closing valves. Thus, by opening the gate valves PGV, the wafer W can be transferred to the vacuum transfer chamber TM under reduced pressure. Furthermore, by closing the gate valves PGV, it is possible to perform various kinds of substrate processing on the wafer W while holding an internal pressure and the processing gas atmosphere in the processing module PM.

The load lock chambers LM serve as spare chambers for loading the wafers W into the vacuum transfer chamber TM, or as a spare chamber for unloading the wafers W from the interior of the vacuum transfer chamber TM. Inside each load lock chamber LM, a buffer stage (not illustrated) is provided as a substrate mounting section for temporarily supporting the wafer W when the wafer W is loaded and unloaded. The buffer stage may be configured as a multistage slot for holding a plurality (for example, two) of the wafers W.

Furthermore, each of the load lock chambers LM is connected to the vacuum transfer chamber TM by a gate valve LGV as an opening/closing valve, and is also connected to an atmospheric pressure transfer chamber EFEM described later, by a gate valve LD as an opening/closing valve. Thus, by opening the gate valve LD on the atmospheric pressure transfer chamber EFEM side while keeping the gate valve LGV on the vacuum transfer chamber TM side closed, it is possible to transfer the wafer W under atmospheric pressure between the load lock chamber LM and the atmospheric pressure transfer chamber EFEM while holding the vacuum tightness in the vacuum transfer chamber TM.

Furthermore, the load lock chambers LM have a structure capable of withstanding a reduced pressure less than atmospheric pressure such as a vacuum state, and the inside of each of the load lock chambers LM can be vacuum-exhausted. Thus, by closing the gate valve LD on the atmospheric pressure transfer chamber EFEM side and vacuum-exhausting the load lock chamber LM and then opening the gate valve LGV on the vacuum transfer chamber TM side, it is possible to transfer the wafer W under reduced pressure between the load lock chamber LM and the vacuum transfer chamber TM while holding the vacuum state in the vacuum transfer chamber TM. As described above, the load lock chambers LM are configured to be switchable between the atmospheric pressure state and the reduced pressure state.

(Atmospheric Pressure Side Configuration)

On the other hand, as described above, the atmospheric pressure side of the substrate processing apparatus is provided with the atmospheric pressure transfer chamber Equipment Front End Module (EFEM) that is a front module connected to the load lock chambers LM1 and LM2, and the load ports LP1 to LP3 that are connected to the atmospheric pressure transfer chamber EFEM and serves as carrier mounting sections for mounting carriers CA1 to CA3 as wafer storage containers each storing, for example, 25 wafers W for one lot. As such carriers CA1 to CA3, for example, Front Opening Unified Pod (FOUP) is used. Here, the load ports LP1 to LP3 will be generally or representatively referred to as a load port LP. The carriers CA1 to CA3 will be generally or representatively referred to as a carrier CA. The same rules apply to the atmospheric pressure side configuration (carrier doors CAH1 to CAH3, carrier openers CP1 to CP3, and the like, which will be described later), like the vacuum side configuration.

In the atmospheric pressure transfer chamber EFEM, for example, one atmospheric pressure robot AR is provided as a transfer means. The atmospheric pressure robot AR is configured to transfer the wafer W between the load lock chamber LM1 and the carrier CA on the load port LP1. Similarly to the vacuum robot VR, the atmospheric pressure robot AR includes two sets of arms ARA that are substrate mounting sections.

The carrier CA1 is provided with a carrier door CAH that is a cap (lid) of the carrier CA. With the door CAH of the carrier CA mounted on the load port LP opened, the wafer W is stored in the carrier CA by the atmospheric pressure robot AR via a substrate loading/unloading port CAA1, and also the wafer W in the carrier CA is unloaded by the atmospheric pressure robot AR.

Furthermore, in the atmospheric pressure transfer chamber EFEM, the carrier opener CP for opening and closing the carrier door CAH is provided adjacent to each load port LP. That is, the atmospheric pressure transfer chamber EFEM is provided adjacent to the load port LP via the carrier opener CP.

The carrier openers CP include a closure that can be in close contact with the carrier door CAH, and a drive mechanism that moves the closure in the horizontal and vertical directions. The carrier opener CP opens and closes the carrier door CAH by moving the closure in the horizontal and vertical directions together with the carrier door CAH while the closure is in close contact with the carrier door CAH.

Furthermore, in the atmospheric pressure transfer chamber EFEM, an aligner AU that is an orientation flat aligning device for performing alignment of the crystal orientation of the wafer W and the like is provided as a substrate position correcting apparatus. Furthermore, the atmospheric pressure transfer chamber EFEM is provided with a clean air unit (not illustrated) for supplying clean air into the atmospheric pressure transfer chamber EFEM.

Each of the load port LP is configured to mount a corresponding one of carriers CA1 to CA3 storing a plurality of substrates W are respectively loaded on the load port LP. In the respective carriers CA, slots (not illustrated) are provided as storages respectively storing the wafers W, for example, 25 slots for the amount of one lot. Each of the load ports LP is configured to read and store a barcode or the like indicating a carrier ID that is attached to the carrier CA and identifies the carrier CA when the carrier CA is mounted.

Next, a controller 10 which controls the overall substrate processing apparatus is configured to control each section of the substrate processing apparatus. The controller 10 includes at least an device controller 11 as an operation section, a transfer system controller 31 as a transfer controller, and a process controller 221 as a processing controller.

The apparatus controller 11 is an interface with an operator together with an operation display section (not illustrated), and is configured to accept operation by the operation or instruction by the operator via the operation display section. An operation screen and information such as various data is displayed on the operation display section. The data displayed on the operation display section is stored in a memory (a storage unit) of the device controller 11.

The transfer system controller 31 includes a robot controller for controlling the vacuum robot VR and the atmospheric pressure robot AR, and is configured to control transfer of the wafer N and execution of work based on instruction from the operator. Furthermore, the transfer system controller 13 performs transfer control of the wafer N in the substrate processing apparatus, by outputting control data (control instruction) for transferring the wafer W, to the vacuum robot VR, the atmospheric pressure robot AR, various valves, switches, and the like, on the basis of, for example, a transfer recipe created or edited by the operator via the device controller 11. Note that, details of the process controller 221 will be described later. Since hardware configurations of each of the controllers 11, 31, and 221 of the controller 10 are also the same as those of the process controller 221 described later, description thereof is omitted here.

The controller 10 may be provided not only inside the substrate processing apparatus as illustrated in FIG. 1 but also outside the substrate processing apparatus. Furthermore, the process controller 221 as a process controller for controlling the apparatus controller 11, the transfer system controller 31, and the processing module PM may be configured as a typical General-purpose computer such as a personal computer, for example. In this case, each controller can be configured by installing a program on a General-purpose computer by using a non-transitory computer-readable recording medium (USB memory, DVD, and the like) storing various programs.

Furthermore, means for supplying a program for executing the above-described processing can be arbitrarily selected. In addition to supplying the program via a predetermined recording medium as described above, the program may be supplied via, for example, a communication line, a communication network, a communication system, or the like. In this case, for example, the program may be posted on a bulletin board of the communication network, and may be supplied by being superimposed on a carrier wave via the network. Then, the above-described processing may be executed by activating the program provided in this way and executing the program in the same manner as other application programs under control of an operating system (OS) of the substrate processing apparatus.

(Processing Chamber)

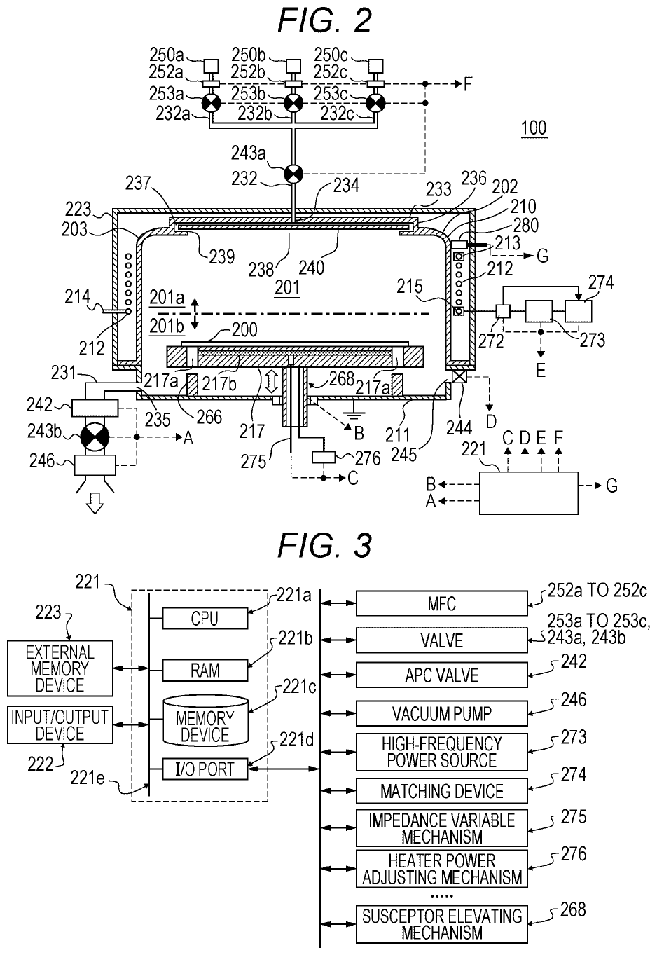

Next, the processing module PM as a processing mechanism according to the first embodiment of this present disclosure will be described with reference to FIG. 2. The processing mechanism PM includes a process furnace 202 for performing plasma processing on the wafer W. The process furnace 202 is provided with a process container 203 including a process chamber 201. The process container 203 includes a quartz dome-shaped upper container 210 (hereinafter also referred to as a quartz dome) that is a first container and a bowl-shaped lower container 211 that is a second container. The process chamber 201 is formed by the upper vessel 210 covering the lower vessel 211. Furthermore, the upper container 210 is provided with a temperature sensor 280 such as a thermocouple so that the temperature of the upper container 210 can be detected. The upper container 210 is formed of a non-metallic material, for example, aluminum oxide (Al₂O₃) or quartz (SiO₂), and the lower container 211 is formed of aluminum (Al), for example.

Furthermore, a gate valve 244 is provided on a lower side wall of the lower container 211. The gate valve 244 is configured to load the wafer W into the processing chamber 201 or unload the wafer W out of the processing chamber 201 via a loading/unloading port 245 by using a transfer mechanism (not illustrated), when the gate valve 244 is opened. The gate valve 244 is configured to be a gate valve for maintaining the airtightness in the process chamber 201, when the gate valve 244 is closed.

The processing chamber 201 includes a plasma generation space 201a (upper side of the one-dot chain line in FIG. 2) around which a coil 212 is provided, and a substrate processing space 201b that communicates with the plasma generation space 201a and in which the wafer W is processed. The plasma generation space 201a is a space in which plasma is generated, and is a space in the process chamber 201 above the lower end of the coil 212 and below the upper end of the coil 212. On the other hand, the substrate processing space 201b (lower side of the one-dot chain line in FIG. 2) is a space in which the substrate is processed by using plasma and is a space below the lower end of the coil 212. In the present embodiment, the horizontal diameters of the plasma generation space 201a and the substrate processing space 201b are configured to be substantially the same as each other.

(Susceptor)

A susceptor 217 serving as a substrate mounting section on which the wafer W is mounted is arranged at the center on the bottom side of the processing chamber 201. The susceptor 217 is formed of, for example, a non-metallic material, such as aluminum nitride (AlN), ceramics, or Quartz, and is configured to be able to reduce metal contamination on a film or the like formed on the wafer W.

A heater 217b as a heating mechanism is integrally embedded in the susceptor 217. The heater 217b is configured to heat the surface of the wafer W, for example, from about 25° C. to about 750° C. when electric power is supplied.

The susceptor 217 is electrically insulated from the lower container 211. An impedance adjustment electrode 217c is provided inside the susceptor 217 to further improve the uniformity of the density of the plasma generated on the wafer W mounted on the susceptor 217, and is grounded via an impedance variable mechanism 275 serving as an impedance adjustment section. The impedance variable mechanism 275 includes a coil and a variable capacitor, and is configured to change the impedance within a range of about 0Ω to the parasitic impedance value of the process chamber 201 by controlling the inductance value and the resistance value of the coil and the capacitance value of the variable capacitor.

The susceptor 217 is provided with a susceptor elevating mechanism 268 including a drive mechanism for moving up and down the susceptor. Furthermore, the susceptor 217 is provided with through-holes 217a, and wafer push-up pins 266 are provided on the bottom surface of the lower container 211. The wafer push-up pins 266 are configured to penetrate through the through-holes 217a in a non-contact state with the susceptor 217 when the susceptor 217 is lowered by the susceptor elevating mechanism 268.

The substrate mounting section according to the present embodiment is mainly configured by the susceptor 217, the heater 217b, and the electrode 217c.

(Gas Supply Section)

A gas supply head 236 is provided above the processing chamber 201, that is, on the upper part of the upper container 210. The gas supply head 236 includes a cap-shaped lid 233, a gas inlet 234, a buffer chamber 237, an opening 238, a shielding plate 240, and a gas outlet 239, and is configured to supply the reactant gas into the processing chamber 201. The buffer chamber 237 serves as a dispersion space for dispersing the reaction gas introduced from the gas inlet 234.

The downstream end of an oxygen-containing gas supply pipe 232a for supplying oxygen (O₂) gas as an oxygen-containing gas, the downstream end of a hydrogen-containing gas supply pipe 232b for supplying hydrogen (H₂) gas as a hydrogen-containing gas, and the downstream end of an inert gas supply pipe 232c for supplying argon (Ar) gas as an inert gas are connected to the gas inlet 234 so that they join. The oxygen-containing gas supply pipe 232a is provided with an O₂ gas supply source 250a, a mass flow controller (MFC) 252a as a flow rate control apparatus, and a valve 253a as an opening/closing valve, in order from the corresponding upstream side. The hydrogen-containing gas supply pipe 232b is provided with an H₂ gas supply source 250b, an MFC 252b, and a valve 253b, in order from the corresponding upstream side. The inert gas supply pipe 232c is provided with an Ar gas supply source 250c, an MFC 252c, and a valve 253c, in order from the corresponding upstream side. A valve 243a is provided on the downstream side where the oxygen-containing gas supply pipe 232a, the hydrogen-containing gas supply pipe 232b, and the inert gas supply pipe 232c joined, and is connected to the upstream end of the gas inlet 234. The gas supply section is configured to be able to supply, into the processing chamber 201, processing gases such as the oxygen-containing gas, the hydrogen gas-containing gas, and the inert gas via the gas supply pipes 232a, 232b, and 232c while adjusting the flow rates of the respective gases by the MFCs 252a, 252b, and 252c, by opening and closing the valves 253a, 253b, 253c, and 243a.

The gas supply section (gas supply system) according to the present embodiment is mainly configured by the gas supply head 236 (lid 233, gas inlet 234, buffer chamber 237, opening 238, shielding plate 240, gas outlet 239), the oxygen-containing gas supply pipe 232a, the hydrogen-containing gas supply pipe 232b, the inert gas supply pipe 232c, the MFCs 252a, 252b, and 252c, and the valves 253a, 253b, 253c, and 243a.

Furthermore, the gas supply head 236, the oxygen-containing gas supply pipe 232a, the MFC 252a, and the valves 253a and 243a constitute an oxygen-containing gas supply system according to the present embodiment. Moreover, the gas supply head 236, the hydrogen-containing gas supply pipe 232b, the MFC 252b, and the valves 253b and 243a constitute a hydrogen gas supply system according to the present embodiment. Moreover, the gas supply head 236, the inert gas supply pipe 232c, the MFC 252c, and the valves 253c and 243a constitute an inert gas supply system according to the present embodiment.

Note that, the substrate processing apparatus according to the present embodiment is configured to perform oxidizing process by supplying the O₂ gas as an oxygen-containing gas from the oxygen-containing gas supply system; however, a nitrogen-containing gas supply system can be provided for supplying a nitrogen-containing gas into the processing chamber 201 instead of the oxygen-containing gas supply system. According to the substrate processing apparatus configured in this way, a nitriding process may be performed instead of oxidizing process of the substrate. In this case, instead of the O₂ gas supply source 250a, for example, an N₂ gas supply source as a nitrogen-containing gas supply source is provided, and the oxygen-containing gas supply pipe 232a is configured as a nitrogen-containing gas supply pipe.

(Exhaust Section)

A gas exhaust port 235 for exhausting the reactant gas from the processing chamber 201 is provided at the side wall of the lower container 211. The upstream end of a gas exhaust pipe 231 is connected to the gas exhaust port 235. The gas exhaust pipe 231 is provided with an Auto Pressure Controller (APC) valve 242 as a pressure regulator (pressure regulating section), a valve 243b as an opening/closing valve, and a vacuum pump 246 as a vacuum-exhaust device, in order from the corresponding upstream side. The exhaust section according to the present embodiment is mainly configured by the gas exhaust port 235, the gas exhaust pipe 231, the APC valve 242, and the valve 243b. Note that, the vacuum pump 246 may be included in the exhaust section.

(Plasma Generator)

The spiral resonance coil 212 as a first electrode is provided at the outer periphery of the processing chamber 201, that is, outside the side wall of the upper container 210 to surround the processing chamber 201. The resonance coil 212 is connected to an RF sensor 272, a high-frequency power source 273, and a matching device 274 for matching an impedance or an output frequency of the high-frequency power source 273. The plasma generator according to the present embodiment is mainly configured by the resonance coil 212, the RF sensor 272, and the matching device 274. Note that, a high-frequency power source 273 may be included as a plasma generator.

The high-frequency power source 273 supplies high-frequency power (RF power) to the resonance coil 212. The RF sensor 272 is provided at the output side of the high-frequency power source 273 and monitors information on a traveling wave and reflected wave of the supplied high-frequency power. The reflected wave power monitored by the RF sensor 272 is input to the matching device 274, and the matching device 274 controls the impedance of the high-frequency power source 273 or the frequency of the output high-frequency power so that the reflected wave is minimized, on the basis of the information on the reflected wave input from the RF sensor 272.

The high-frequency power source 273 includes a power source control means (control circuit) including a high-frequency oscillation circuit and a preamplifier for defining the oscillation frequency and an output, and an amplifier (output circuit) for amplifying the same to a predetermined output. The power source control means controls the amplifier based on output conditions regarding frequency and power set in advance through an operation panel. The amplifier supplies constant high-frequency power to the resonance coil 212 via a transmission line.

To form a standing wave having a predetermined wavelength, the winding diameter, the winding pitch, and the number of turns of the resonance coil 212 are set to resonate at a constant wavelength. That is, the electrical length of the resonance coil 212 is set to a length corresponding to an integral multiple (1×, 2×, . . . ) of one wavelength at a predetermined frequency of the high-frequency power supplied from the high-frequency power source 273.

As a material constituting the resonance coil 212, a copper pipe, a copper thin plate, an aluminum pipe, an aluminum thin plate, a material in which copper or aluminum is deposited on a polymer belt, or the like is used. The resonance coil 212 is formed of an insulating material in a flat plate shape, and is supported by a plurality of supports (not illustrated) vertically provided on the upper end surface of a base plate 248.

(Controller)

As illustrated in FIG. 3, the controller 221 as the process controller is configured to control: the APC valve 242, the valve 243b, and the vacuum pump 246, via a signal line A; the susceptor elevating mechanism 268 via a signal line B; a heater power adjusting mechanism 276 and the impedance variable mechanism 275, via a signal line C; the gate valve 244 via a signal line D; the RF sensor 272, the high-frequency power source 273, and the matching device 274, via a signal line E; and the MFCs 252a to 252c, and the valves 253a to 253c, and 243a, via a signal line F respectively.

The controller 221 that is a process controller is configured as a computer including a Central Processing Unit (CPU) 221a, a Random-Access Memory (RAM) 221b, a memory device 221c, and an I/O port 221d. The RAM 221b, the memory device 221c, and the I/O port 221d are configured to exchange data with the CPU 221a via an internal bus 221e. For example, an input/output device 222 configured as a touch panel or a display is connected to the controller 221.

The memory device 221c is configured by, for example, a flash memory, a Hard Disk Drive (HDD), or the like. In the memory device 221c, a control program for controlling operation of the substrate processing apparatus, a program recipe specifying sequences and conditions of the substrate processing described later, or the like are readably stored. A process recipe (processing recipe) or various program recipes such as a chamber condition recipe as a pre-processing recipe and the like as described below function as a program combined such that the process control part 221 executes each sequence so as to obtain a predetermined result. Hereinafter, the program recipe, the control program, and the like are also collectively referred to simply as a program. Note that, when the term “program” is used in this specification, it may include a program recipe alone, may include a control program alone, or may include both. Furthermore, the RAM 221b is configured as a memory area (work area) in which programs, data, and the like read by the CPU 221a are temporarily held.

The I/O port 221d is connected to the above-described MFCs 252a to 252c, valves 253a to 253c, 243a, and 243b, gate valve 244, APC valve 242, vacuum pump 246, RF sensor 272, high-frequency power source 273, matching device 274, susceptor elevating mechanism 268, impedance variable mechanism 275, heater power adjusting mechanism 276, and the like.

The CPU 221a is configured to read and execute a control program from the memory device 221c, and to read a process recipe from the memory device 221c in response to input of an operation command from the input/output device 222, or the like. Then, the CPU 221a is configured to control: opening degree adjusting operation of the APC valve 242, opening/closing operation of the valve 243b, and start/stop of the vacuum pump 246, via the I/O port 221d and the signal line A; elevating operation of the susceptor elevating mechanism 268 via the signal line B; supply power amount adjusting operation (temperature adjusting operation) to the heater 217b by the heater power adjusting mechanism 276, and impedance value adjusting operation by the impedance variable mechanism 275, via the signal line C; opening/closing operation of the gate valve 244 via the signal line D; operations of the RF sensor 272, the matching device 274, and the high-frequency power source 273, through the signal line E; flow rate adjusting operation of various gases by the MFCs 252a to 252c, and opening/closing operation of the valves 253a to 253c, and 243a, via the signal line F; and the like in accordance with the contents of the read process recipe.

The processing controller 221 may be configured by installing, on a computer, the above-described program stored in an external memory device (for example, a semiconductor memory such as a USB memory or a memory card) 223. The memory device 221c or the external memory device 223 is configured as a non-transitory computer-readable recording media. Hereinafter, these are also collectively referred to simply as a recording medium. In this specification, when the term “recording medium” is used, it may indicate a case where the memory device 221c alone is included, a case where the external memory device 223 alone is included, or a case where the both are included. Note that, the provision of the program to the computer may be performed by using a communication means such as the Internet or a dedicated line, instead of using the external memory device 223.

### (2) Substrate Processing Step

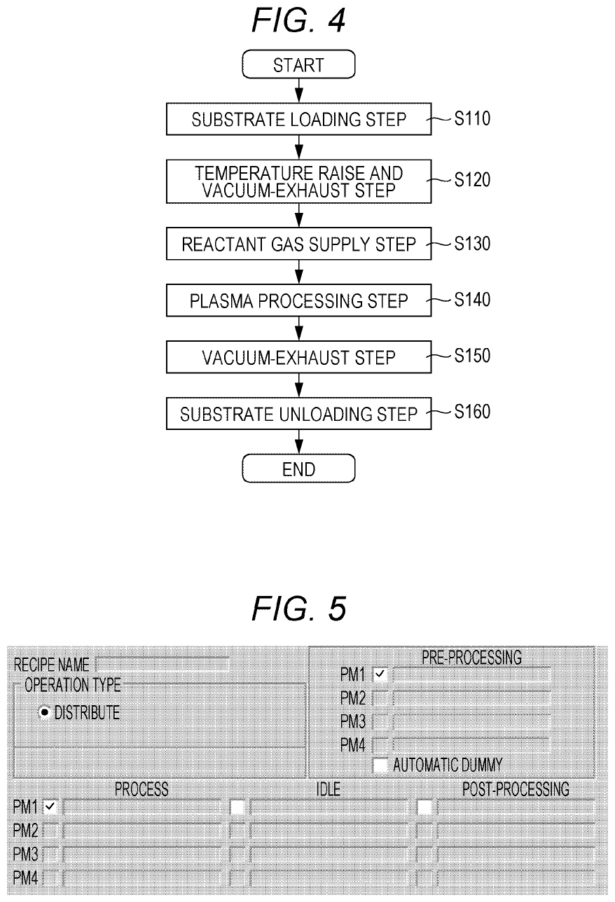

FIG. 4 is a flow diagram illustrating a substrate processing step as a processing recipe according to the present embodiment. The substrate processing step according to this embodiment, which is one of the step for manufacturing a semiconductor device, is performed by, for example, the above-described processing mechanism PM. In the following description, operation of each section constituting the processing mechanism PM is controlled by the process controller 221.

(Substrate Loading Step S110)

First, the susceptor elevating mechanism 268 lowers the susceptor 217 to a transfer position of the wafer W, and causes the wafer push-up pins 266 to pass through the through-holes 217a of the susceptor 217. As a result, the wafer push-up pins 266 protrude from the surface of the susceptor 217 by a predetermined height.

Subsequently, the gate valve 244 is opened, and the wafer N is loaded into the processing chamber 201 from a vacuum transfer chamber adjacent to the processing chamber 201 by using a wafer transfer mechanism (not illustrated). The loaded wafer W is supported in a horizontal posture on the wafer push-up pins 266 protruding from the surface of the susceptor 217. When the wafer W is loaded into the process chamber 201, the wafer transfer mechanism is retracted to the outside of the process chamber 201, and the gate valve 244 is closed to seal the interior of the process chamber 201. Then, the susceptor elevating mechanism 268 raises the susceptor 217 such that the wafer W is supported on the upper surface of the susceptor 217.

(Temperature Raise and Vacuum-Exhaust Step S120)

Subsequently, the temperature of the wafer W loaded into the processing chamber 201 is raised. The heater 217b is preheated, and the wafer W is heated to a predetermined value within a range of 150 to 750 degrees C., for example, by holding the wafer W on the susceptor 217 in which the heater 217b is embedded. Here, the wafer H is heated such that the temperature of the wafer W becomes 600 degrees C. Furthermore, while the temperature of the wafer W is raised, the inside of the processing chamber 201 is vacuum-exhausted by the vacuum pump 246 via the gas exhaust pipe 231 to set the pressure in the processing chamber 201 to a predetermined value. The vacuum pump 246 is operated at least until a substrate unloading step S160 described later is ended.

(Reactant Gas Supply Step S130)

Next, supply is started of O₂ gas that is an oxygen-containing gas, and H₂ gas that is a hydrogen-containing gas, as reaction gases. Specifically, the valves 253a and 253b are opened, and the supply is started of the O₂ gas and the H₂ gas into the processing chamber 201 while the flow rate of the O2 gas and the H2 gas are controlled by the MFCs 252a and 252b. At this time, the flow rate of the O₂ gas may be set at a predetermined value which falls within a range of, for example, 20 to 2000 sccm, and preferably 20 to 1000 sccm. Furthermore, the flow rate of the H₂ gas may be set at a predetermined value which falls within a range of, for example, 20 to 1000 sccm, or preferably 20 to 500 sccm. As a more preferred example, it is desirable that a total flow rate of the O₂ gas and H₂ gas be set to 1000 sccm, and the flow rate ratio thereof be set to O₂/H₂≥950/50.

Furthermore, exhaust in the process chamber 201 is controlled by adjusting the degree of opening of the AFC valve 242 so that the pressure in the process chamber 201 becomes equal to a predetermined pressure which falls in a range of, for example, 1 to 250 Pa, preferably 50 to 200 Pa, and more preferably about 150 Pa. As described above, while the inside of the processing chamber 201 is appropriately exhausted, the supply of the O₂ gas and H₂ gas is continuously performed until a plasma processing step S140 described later is completed.

(Plasma Processing Step S140)

When the pressure in the processing chamber 201 is stabilized, the application is started of high-frequency power to the resonance coil 212 from the high-frequency power source 273 via the RF sensor 272. In the present embodiment, high-frequency power of 27.12 MHz is supplied from the high-frequency power source 273 to the resonance coil 212. The high-frequency power supplied to the resonance coil 212 may be set at predetermined electric power which falls within a range of, for example, 100 to 5000 W, preferably 100 to 3500 W, or more preferably about 3500 W. When the electric power is lower than 100 W, it is difficult to generate plasma discharge stably.

As a result, a high-frequency electric field is formed in the plasma generation space 201a to which the O₂ gas and H₂ gas are supplied, and the electric field excites a donut-shaped induction plasma having the highest plasma density at a height position corresponding to the electrical midpoint of the resonance coil 212 in the plasma generation space. Plasma-like O₂ gas and H₂ gas are dissociated, and reactive species are generated such as oxygen ions and oxygen radicals (oxygen active species) containing oxygen, hydrogen ions and hydrogen radicals (hydrogen active species) containing hydrogen.

As described above, when the electrical length of the resonance coil 212 is the same as the wavelength of the high-frequency power, there is almost no capacitive coupling with a process chamber wall and a substrate mounting table in the vicinity of the electrical midpoint of the resonance coil 212, in the plasma generation space 201a, and the donut-shaped induction plasma is excited having an extremely low electric potential. Since the plasma is generated having the extremely low electric potential, it is possible to prevent a sheath from being generated on the wall of the plasma generation space 201a or the susceptor 217. Thus, in this embodiment, ions in the plasma are not accelerated.

On the wafer W held on the susceptor 217 in the substrate processing space 201b, radicals generated by the induction plasma and ions in an unaccelerated state are uniformly supplied into a groove 301. The supplied radicals and ions react uniformly with side walls 301a and 301b, to modify a silicon layer on the surface into a silicon oxide layer having good step coverage.

Thereafter, when a predetermined processing time, for example, 10 to 300 seconds elapses, the output of the electric power from the high-frequency power source 273 is stopped, and plasma discharge in the processing chamber 201 is stopped. Furthermore, the valves 253a and 253b are closed, and the supply of the O₂ gas and H₂ gas into the processing chamber 201 is stopped. Thus, plasma processing step S140 is ended.

(Vacuum Exhaust Step S150)

When the supply of the O₂ gas and H₂ gas is stopped, the inside of the process chamber 201 is vacuum-exhausted via the gas exhaust pipe 231. As a result, the O₂ gas and H₂ gas in the process chamber 201, an exhaust gas generated by the reaction of these gases, or the like is exhausted to the outside of the process chamber 201. Thereafter, the pressure in the process chamber 201 is adjusted to the same pressure (for example, 100 Pa) equal to that of the vacuum transfer chamber (unloading destination of the wafer W. Not illustrated) adjacent to the process chamber 201 by adjusting the opening degree of the APC valve 242.

(Substrate Unloading Step S160)

When the inside of the process chamber 201 reaches a predetermined pressure, the susceptor 217 is lowered to the transfer position of the wafer W, and the wafer W is supported on the wafer push-up pins 266. Then, the gate valve 244 is opened, and the wafer W is unloaded to the outside of the process chamber 201 by using the wafer transfer mechanism. Thus, the substrate processing step according to the present embodiment is completed.

Next, with reference to FIGS. 5 to 7, execution control of a pre-processing recipe (chamber condition recipe) by the controller 10 will be described.

First, the setting of the pre-processing recipe will be described. Various recipes including the pre-processing recipes can be specified on a sequence recipe editing screen illustrated in FIG. 5.

The sequence recipe editing screen is configured to include a column for entering a name of a sequence recipe, an area for setting the pre-processing recipe for each processing mechanism PM, a warm-up recipe as an idle recipe for each processing apparatus, a process recipe as a substrate processing recipe, and an area for setting, a post-processing recipe for each processing mechanism PM, and an area for selecting an operation type of the substrate processing apparatus.

In the area where the pre-processing recipe is set for each processing mechanism PM, a column for setting the pre-processing recipe for setting a target temperature is provided for each processing mechanism PM. Furthermore, a column (automatic execution setting column) is provided for setting specification for confirming the target temperature before the process recipe automatically in all the processing mechanisms PM, and when this column is checked, the pre-processing recipe is continued until the temperature of the upper container 210 constituting the process chamber 201 of all the processing mechanisms PM reaches the target temperature. When all the processing mechanisms PM reach the target temperature, the pre-processing recipe is completed.

In the sequence recipe editing screen illustrated in FIG. 5, when there is an execution setting for the pre-processing recipe and there is no automatic execution setting (when the automatic execution setting column is not checked), the pre-processing recipe is executed in each processing mechanism PM after completion of the idle recipe, and when a recipe completion report is issued from the processing mechanism PM specified for execution, automatic operation processing (execution of the process recipe) is performed. As described above, when the pre-processing recipe of the processing mechanism PM1 is completed, the processing proceeds to the next processing (substrate processing), whereby it is possible to adapt a case where priority is given to the throughput over the temperature of the upper container 210 constituting the process chamber 201.

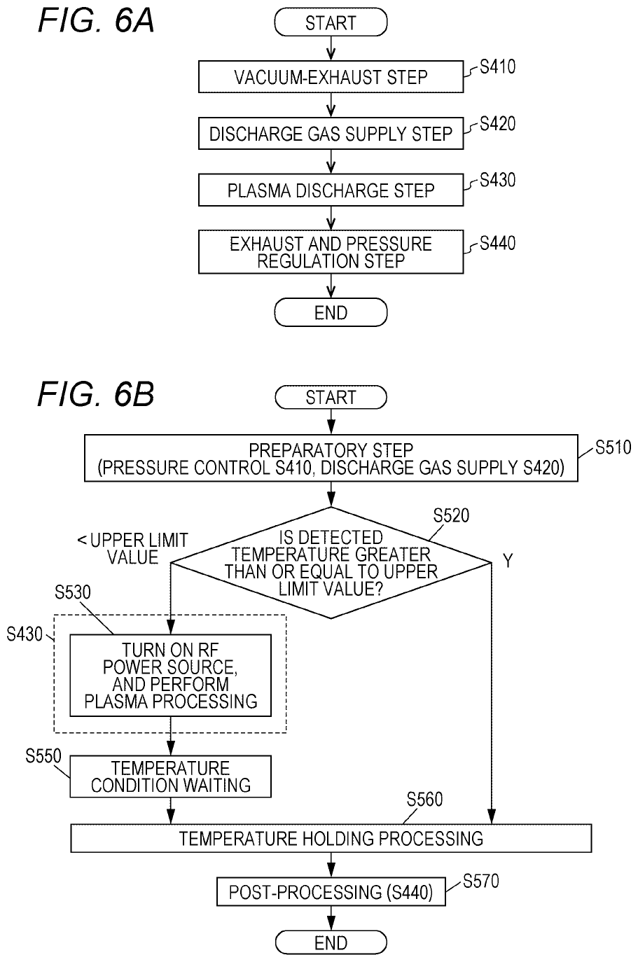

Hereafter, each step constituting the pre-processing step as the pre-processing recipe will be described with reference to FIG. 6A. The pre-processing step may also be performed with the wafer W as a dummy substrate is mounted on the susceptor 217, but an example will be described in which the dummy substrate is not used.

(Vacuum-Exhaust Step S410)

First, the processing chamber 201 is vacuum-exhausted by the vacuum pump 246 such that the pressure of the process chamber 201 becomes a predetermined value. The vacuum pump 246 is operated at least until an exhaust and pressure regulation step S440 is completed. In addition, the heater 217b is controlled to heat the susceptor 217, similarly.

(Discharge Gas Supply Step S420)

Next, as a discharge gas, a mixed gas of the O2 gas and H2 gas is supplied into the process chamber 201, similar to the reaction gas in the process recipe illustrated in FIG. 4. The specific gas supply procedure and conditions such as a supply gas flow rate and pressure in the processing chamber 201 are the same as those in the processing recipe illustrated in FIG. 4.

Note that, for the purpose of promoting plasma discharge in the plasma discharge step S430 described later, another gas such as Ar gas may be supplied, or at least one of the O2 gas or H2 gas may be caused to be not supplied. Furthermore, different conditions may be set for the conditions such as the supply gas flow rate and the pressure in the process chamber 201. However, an aspect in which the same discharge gas is used as the reaction gas in the process recipe illustrated in FIG. 4 is one of preferred aspects, since there is an effect of bringing the environment of the processing chamber 201 closer to a stable state of the next processing recipe in addition to heating the upper container 210.

(Plasma Discharge Step S430)

Next, the application is started of high-frequency power from the high-frequency power source 273 to the resonance coil 212. The magnitude of the high-frequency power supplied to the resonance coil 212 may be similar to that of the process recipe illustrated in FIG. 4. However, the magnitude of the high-frequency power may be set larger than that of the process recipe illustrated in FIG. 4 or may be varied within a range of 100 to 5000 W in accordance with other processing conditions, in order to promote plasma discharge.

As a result, the plasma discharge is intensively generated in the plasma generation space 201a, particularly at the respective height positions of the upper end, middle point, and lower end of the resonance coil 212. The generated plasma discharge heats the upper container 210 from the inside. In particular, a portion of the upper container 210 corresponding to the above-described height position where plasma discharge is generated intensively and the vicinity thereof are heated intensively.

The controller 221 measures (monitors) the temperature of the outer peripheral surface of the upper container 210 (the temperature of the plasma generation space 201a) at least during this step by the temperature sensor 280, and continues application of high-frequency power to the resonance coil 212 until this measured temperature becomes greater than or equal to the target temperature (first temperature), to maintain the plasma discharge. When it is detected that the measured temperature has become higher than or equal to the target temperature, the controller 221 stops the supply of the high-frequency power from the high-frequency power source 273 and stops the supply of the discharge gas to the processing chamber 201, and completes this step.

As described above, by generating the plasma discharge until the measured temperature by the temperature sensor 280 becomes higher than or equal to the target temperature to heat the upper container 210 and the like, the thickness of the film formed in the process recipe illustrated in FIG. 4 subsequent to this step can fall within a predetermined deviation range. Here, as the target temperature, it is desirable to acquire a value of a stable temperature at that time by continuously executing the processing recipe illustrated in FIG. 4 in advance. In short, the stable temperature is set as the target temperature.

(Exhaust and Pressure Regulation Step S440)

The gas in the processing chamber 201 is exhausted out of the Processing chamber 201. Thereafter, the opening degree of the APC valve 242 is adjusted so that the pressure of the processing chamber 201 becomes equal to that of the vacuum transfer chamber. As a result, the pre-processing step is completed, and the lot processing illustrated in FIG. 4 is subsequently executed.

Next, FIG. 6B illustrates a flow of the pre-processing recipe when two threshold values (upper limit value and lower limit value) are set and a range is given to the target temperature. When there is a lot processing start request, the controller 221 starts the pre-processing recipe illustrated in FIG. 6B. Furthermore, temperature detection of the quartz dome 210 by the temperature sensor 280 is also started. Thereafter, temperature detection is performed at least until the pre-processing recipe is completed.

(Preparatory Step S510)

First, a preparatory step before generating plasma is executed. Specifically, vacuum-exhaust step S410 and discharge gas supply step S420 illustrated in FIG. 4 are executed. Thus, details thereof will be omitted.

(Comparison Step S520)

It is compared whether or not the temperature (detected temperature) of the temperature sensor 280 is lower than or equal to the upper limit value of the target temperature. When the temperature is lower than the upper limit value of the target temperature, the high-frequency power source 273 is turned on, high-frequency power is supplied to the process chamber 201, and plasma processing is performed (S530), and the processing proceeds to the next step (S550). Since details of the plasma processing have been described in plasma discharge step S430, details thereof are omitted. As a result, the temperature of the quartz dome 210 is increased.

Furthermore, if the upper limit value of the target temperature is exceeded, the high-frequency power source 273 remains off, and the processing proceeds to the next step (S560) without performing plasma processing.

FIG. 6B is merely an embodiment, and the flow may be performed such that if the temperature (detected temperature) of the temperature sensor 280 is lower than or equal to the lower limit value of the target temperature, the high-frequency power source 273 is turned on, high-frequency power is supplied to the process chamber 201, and the plasma processing is performed (S530), and the processing proceeds to the next step (S550), and if the temperature is higher than the lower limit value of the target temperature, the high-frequency power source 273 remains off and the processing proceeds to the next step (S560).

(Monitoring Step S550)

The controller 221 waits until the detected temperature by the temperature sensor 280 exceeds the upper limit value of the target temperature.

Furthermore, when the temperature of the quartz dome 210 is raised by the plasma processing (S530), the high-frequency power source 273 is turned off at the time when the detected temperature reaches the upper limit value of the target temperature, and the processing proceeds to the next step (S560). Although not illustrated in FIG. 6B, when the upper limit value of the target temperature is not reached even after a predetermined period has elapsed, the pre-processing recipe may be stopped.

(Temperature Holding Step S560)

The controller 221 performs control so that the detected temperature falls within a range of the upper and lower limit values of the target temperature, and notifies the transfer system controller 31 that the processing has proceeded to the temperature holding step S560.

For example, when the upper limit value of the target temperature is reached (S550) by the plasma processing (S530), the plasma processing is stopped (the high-frequency power source 273 is turned off). On the other hand, when the temperature of the quartz dome 210 is lowered while the high-frequency power source 273 is turned off, and when the detected temperature by the temperature sensor 280 is lowered to the target temperature, the plasma processing illustrated in S530 is performed.

In this step, the controller 221 compares the detected temperature with the upper and lower limit values of the target temperature on a regular cycle (at regular intervals), turns on and off the high-frequency power source 273, and when the plasma detected temperature becomes lower than the lower limit value of the target temperature, the plasma processing (S530) is performed. Thereafter, as described above, the high-frequency power source 273 is turned on and off to hold the detected temperature within the range of the upper and lower limit values of the target temperature.

When the transfer system controller 31 receives, from the controller 221 of all the connected processing mechanisms PM (PM1 to PM4), the notification that the processing has proceeded to the processing of temperature holding step S560, the controller 31 instructs the controller 221 of all the processing mechanisms PM (PM1 to PM4) to proceed to the processing of post-processing step S580. On the other hand, when the temperature of the quartz dome 210 in the processing mechanism PM does not fall within the range of the upper and lower limit values of the target temperature for one of all the processing mechanisms PM, the pre-processing recipe is continuously executed. In this case, the controller 221 of the processing mechanism PM in which the temperature of the quartz dome 210 falls within the range of the upper and lower limit values of the target temperature is configured to continuously executes the temperature holding step (S560). In addition, the controller 221 of the processing mechanism PM, which falls within the range of the upper and lower limit values of the target temperature, may simply wait until the temperature of the quartz dome 210 in other processing mechanisms PM reaches the upper and lower limit values of the target temperature, by continuously executing the temperature holding process (S560).

(Post-Processing Step S580)

The controller 221 performs post-processing upon receipt of an instruction from the transfer system controller 31 to proceed to the processing in post-processing step S580. The contents of the post-processing are omitted since they have already been described in exhaust and pressure regulation step S440 illustrated in FIG. 4. The post-processing is ended, whereby the pre-processing recipe is completed. Then, the controller 221 notifies the transfer system controller 31 that the pre-processing recipe has been completed.

When the pre-processing recipe for all the PMs (PM1 to PM4) is completed, the transfer system controller 31 transfers the product wafers to be processed in the lot processing to the process chamber 201, and then the process recipe is performed.

Here, the controller 221 may voluntarily monitor the temperature of the Quartz dome 210 so that the temperature of the quartz dome 210 may be lowered and not deviate from the target temperature until the process recipe starts, and may monitor the temperature of the Quartz dome 210 at regular intervals (on a regular cycle) so that the temperature of the quartz dome 210 falls within the range of the upper and lower limit values of the target temperature, by automatically performing on/off control of the high-frequency power source, to generate discharge plasma.

As described above, according to the pre-processing recipe illustrated in FIG. 6(B), the plasma discharge is generated and the quartz dome 210 and the like are heated, until the measured temperature of the temperature sensor 280 becomes higher than or equal to the target temperature, or until the measured temperature converses within the range of the upper and lower limit values of the target temperature, whereby the thickness of the film formed in the processing recipe illustrated in FIG. 4 subsequent to this step (execution of the pre-processing recipe) can fall within the predetermined deviation range.

Furthermore, according to the pre-processing recipe illustrated in FIG. 6 that does not use a dummy wafer, since the internal temperature of the quartz dome is raised by the plasma processing by processing several dummy wafers and a production process is then performed, it is possible to reduce the decrease in productivity, and the inconvenience of use that the dummy wafer has to be used.

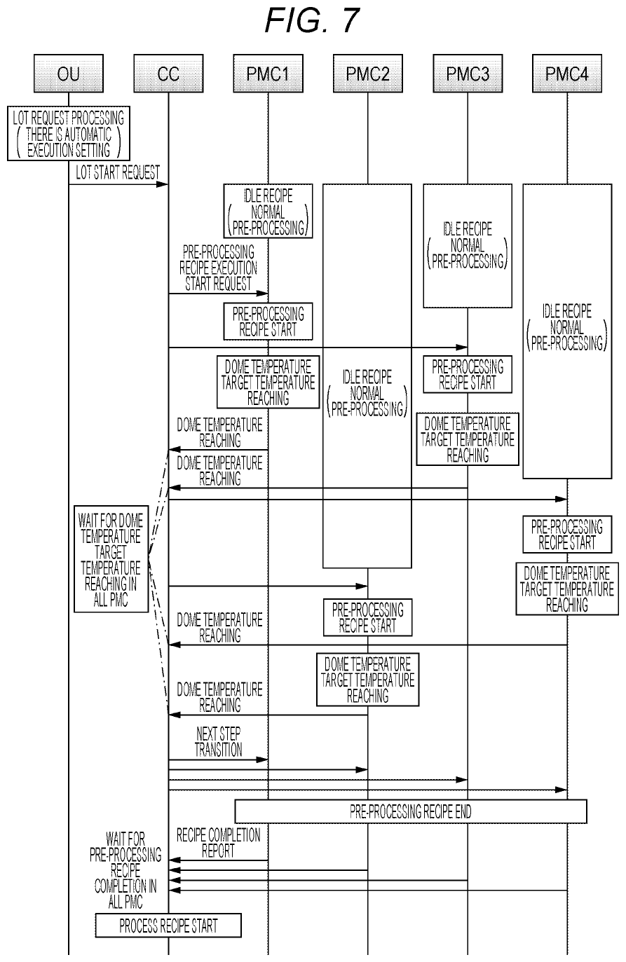

FIG. 7 illustrates a flow of the pre-processing recipe for the entire substrate processing apparatus. In FIG. 7, when the execution setting of the pre-processing recipe and the automatic execution setting are made, the pre-processing recipe is executed until the target temperature is reached in each processing mechanism PM after the idle recipe is completed, and when the completion report of the pre-processing recipe is received from the processing mechanism PM specified to be executed, the automatic operation processing (execution of process recipe) is performed.

Here, the idle recipe is executed when the processing mechanism PM is in an idle (standby) state. The process recipe is executed when the processing mechanism PM is in a run (execution) state. Since the state of the processing mechanism PM is changed from the waiting state to the execution state through the preparation state (standby state) until the process recipe is executed after the idle recipe is completed, the atmosphere of the process chamber 201 of the processing mechanism PM is at a high temperature state to some extent after the idle recipe is completed. However, it was not clear whether or not the atmosphere of the process chamber 201 is at a high temperature state when the process recipe is executed.

Moreover, the idle recipe has been executed at a predetermined time period, but the temperature of the plasma generation space 201a cannot have been grasped. In the present embodiment, the pre-processing recipe can be executed immediately before the process recipe is executed such that the temperature of the plasma generation space 201a of each processing mechanism PM is controlled within the range of the upper and lower limit values of the target temperature. Note that, in the present embodiment, the pre-processing recipe may be executed before the process recipe is executed when the processing mechanism PM is in the run (execution) state.

The control in each processing mechanism PM is as illustrated in FIG. 6 described above. Here, the controller 221 for controlling the processing mechanism PM1 is described as PMC1, described as PMC2 for the processing mechanism PM2, described as PMC3 for the processing mechanism PM3, and described as PMC4 for the processing mechanism PM4. At this time, the apparatus controller 11 is described as CU, and the transfer system controller 31 is described as CC.

The CC that has received a lot start request from the device controller 11 by operation of an operator, or from a higher controller such as a host computer, confirms the completion of an idle recipe such as a warm-up recipe, to the controller 221 for controlling each processing mechanism PM. Note that, if the idle recipe is being executed, a request to execute the pre-processing recipe is suspended, and after the idle recipe is completed, a pre-processing recipe execution request is issued to each processing mechanism PM. In the illustrated example, the temperature of the upper container 210 is lower than the target temperature.

The CC waits for the temperature of the upper container 210 constituting the process chamber 201 to reach the target temperature. Each PMC performs processing (executes pre-processing recipe) in accordance with a recipe name specified in FIG. 5. Furthermore, each processing mechanism PM reports an event to the CC when the temperature of the upper container 210 reaches the target temperature during execution of the pre-processing recipe, and temporarily stops the corresponding step.

Upon receipt of a temperature reaching event in which the temperatures of the upper containers 210 in all the processing mechanisms PM have reached the target temperature, the CC requests each PMC to proceed to the processing of the next step. Each PMC resumes the pre-processing. Upon receipt of a pre-processing recipe completion event from all the PMCs, the CC causes the processing controller to execute the process recipe to start the lot processing.

According to the present embodiment, the controller 221 voluntarily monitors the temperature of the quartz dome 210 so that the temperature of the quartz dome 210 may be lowered and not deviate from the target temperature until the process recipe starts, and performs monitoring at regular intervals so that the temperature of the quartz dome 210 falls within the range of the upper and lower limit values of the target temperature, by automatically performing on/off control of the high-frequency power source, to generate discharge plasma, and therefore the thickness of the film formed in the processing recipe can fall within the predetermined deviation range.

Furthermore, according to the present embodiment, the temperature of the quartz dome 210 is controlled to fall within the range of the upper and lower limit values of the target temperature in all the processing mechanisms PM, and therefore no difference due to the atmosphere of the processing mechanism PM (process chamber 201) occurs in the processing result of the substrate W formed in each processing mechanism PM and processed in the process chamber 201 at the next process (execution of process recipe). Therefore, it is possible to improve the quality of the processing result of the substrate W.

### OTHER EMBODIMENTS OF THE PRESENT DISCLOSURE

In the above-described embodiments, there has been described examples in which the oxidizing process and the nitriding process are performed on the surface of the substrate by using plasma. however, the present disclosure is not limited to thereto and may be applied to any technique that performs processing on a substrate by using plasma. For example, the present disclosure may be applied to a modification process or a doping process for a film formed on a surface of a substrate using plasma, a reduction process for an oxide film, an etching processing for the film, an asking process for a resist, or the like.

This application claims the benefit of priority based on Japanese Patent Application No. 2017-179484 filed on Sep. 20, 2017, the entire disclosure of which is incorporated herein by reference.

This present disclosure can be applied to a processing apparatus that performs processing on a substrate by using plasma.

According to this present disclosure, it is possible to suppress a decrease in productivity by shortening the time spent for pre-processing before a process recipe for processing a product lot.

1. A substrate processing apparatus comprising: at least one processing container including a plasma generation space in which a processing gas is plasma-excited and a substrate processing space communicating with the plasma generation space; a plasma generator including a coil arranged to surround the plasma generation space and provided to be wound around an outer periphery of at least one of the processing containers, and a high-frequency power source that supplies high-frequency power to the coil; a gas supply section that supplies the processing gas to the plasma generation space; at least one temperature sensor provided outside at least one of the processing containers and configured to detect a temperature of at least one of the processing containers; and a controller configured to control the plasma generator and the gas supply section to cause the temperature of at least one of the processing containers detected by at least one of the temperature sensors to fall within a range of a target temperature defined by a preset upper limit value and a preset lower limit value, prior to execution of a process recipe for processing a substrate.

2. The substrate processing apparatus according to claim 1, wherein at least one of the processing containers includes an upper container and a lower container, and at least one of the temperature sensors is provided in the upper container.

3. The substrate processing apparatus according to claim 1, wherein the controller is configured to execute a pre-processing recipe before the process recipe, and the pre-processing recipe is configured to supply, to the coil, high-frequency power for plasma-exciting the processing gas.

4. The substrate processing apparatus according to claim 3, wherein the pre-processing recipe is configured not to transfer the substrate.

5. The substrate processing apparatus according to claim 1, wherein the controller is configured to supply the high-frequency power to the coil to raise the temperature of at least one of the processing containers in a case where the temperature detected by at least one of the temperature sensors is lower than the lower limit value of the target temperature.

6. The substrate processing apparatus according to claim 1, wherein the controller is configured not to supply the high-frequency power to the coil in a case where the temperature detected by at least one of the temperature sensors is higher than the upper limit value of the target temperature.

7. The substrate processing apparatus according to claim 1, wherein the controller is configured to turn on the high-frequency power source to supply the high-frequency power to the coil to raise the temperature of at least one of the processing containers when the temperature detected by at least one of the temperature sensors is lower than the lower limit value of the target temperature, and to turn off the high-frequency power source to lower the temperature of at least one of the processing containers when the temperature detected by at least one of the temperature sensors exceeds the upper limit value of the range of the target temperature.

8. The substrate processing apparatus according to claim 3, wherein the controller is configured to complete the pre-processing recipe when the temperature detected by at least one of the temperature sensors is higher than the lower limit value of the range of the target temperature and lower than the upper limit value of the range of the target temperature.

9. The substrate processing apparatus according to claim 3, at least one of the process containers includes a plurality of the processing containers, and
wherein the controller is configured to complete the pre-processing recipe when the temperatures detected by at least one of the temperature sensors respectively provided for the processing containers is higher than the lower limit value of the range of the target temperature and lower than the upper limit value of the range of the target temperature.

10. The substrate processing apparatus according to claim 9, wherein the controller is configured to distribute and transfer the substrate to each of substrate process chambers respectively formed in the processing containers, and to execute the process recipe individually.

11. The substrate processing apparatus according to claim 3, at least one of the process containers includes a plurality of the processing containers, wherein the controller is configured to continue the pre-processing recipe when the temperature detected by at least one of temperature sensors respectively provided for the processing containers is higher than the upper limit value of the range of the target temperature or when the temperature detected by at least one of temperature sensors respectively provided for the processing containers is lower than the lower limit value of the range of the target temperature.

12. The substrate processing apparatus according to claim 9, wherein the controller is further configured to execute an idle recipe, and wherein the pre-processing recipe is configured to be executed after the idle recipe.

13. A non-transitory computer-readable recording medium storing a program executed by a substrate processing apparatus comprising:
at least one processing container including a plasma generation space in which a processing gas is plasma-excited and a substrate processing space communicating with the plasma generation space;
a plasma generator including a coil arranged to surround the plasma generation space and provided to be wound around an outer periphery of at least one of the processing containers, and a high-frequency power source that supplies high-frequency power to the coil;
a gas supply section that supplies the processing gas to the plasma generation space;
at least one temperature sensor provided outside at least one of the processing containers and configured to detect a temperature of at least one of the processing containers; and
a controller configured to control the plasma generator, and the gas supply section;
wherein the program causes the controller to perform: detecting the temperature of the processing container;
supplying the processing gas to the plasma generation space;
plasma-exciting the processing gas supplied to the plasma generation space by supplying high-frequency power; and
causing the temperature of the processing container to fall within a range of a target temperature defined by a preset upper limit value and a preset lower limit value, prior to execution of a process recipe for processing a substrate.
